(19) United States
(12) Patent Application Publication
(10) Pub. No.: US 2010/0055401 A1
(43) Pub. Date: Mar. 4, 2010

(54) MANUFACTURING METHOD OF FILM HAVING MICRO-PATTERN THEREON AND FILM MANUFACTURED THEREBY

(75) Inventors: Hyun Seok Choi, Daejeon (KR); Yeon Keun Lee, Daejeon (KR); Chan Hyo Park, Daejeon (KR); Bo Yun Choi, Daejeon (KR); Kwang Joo Lee, Daejeon (KR)

Correspondence Address: MCKENNA LONG & ALDRIDGE LLP, 1900 K STREET, NW, WASHINGTON, DC, 20006, US

(73) Assignee: LG CHEM, LTD., Seoul (KR)

(21) Appl. No.: 12/312,860

(22) PCT Filed: Mar. 28, 2008
(86) PCT No.: PCT/KR2008/001754

§ 371 Date: May 29, 2009

(30) Foreign Application Priority Data
Mar. 30, 2007 (KR) 10-2007-0031478

(51) Int. Cl. B32B 3/00; G03F 7/20

(52) U.S. Cl. 428/156; 430/322; 430/325

(57) ABSTRACT

A method of efficiently manufacturing a film having micro-patterns and an optical film manufactured using the same are used for various optical purposes. The method includes forming a first micro-pattern on one face of the film, and forming a second micro-pattern, which has a geometry equal to that of the first micro-pattern, on the other face of the film by a photo-lithography method using the first micro-pattern formed on one face of the film as a photomask.

### TECHNICAL FIELD

The present invention relates to a manufacturing method of a film having micro-patterns thereon and a film manufactured thereby and, more particularly, to a method of efficiently manufacturing a film having micro-patterns, capable of being used for various optical purposes, and an optical film manufactured using the same.

### BACKGROUND ART

When attached to, for instance, a display device, a film is made of a transparent material so as to enable emitted light (of an image) to reach the eyes of an observer. For various reasons, however, such a film does not merely transmits the light, but transmits only the light meeting specific conditions to improve a quality of image of the display device.

For example, the film is used to improve a contrast in various display devices such as plasma display panel (PDP), liquid crystal display (LCD), rear projection television (RPTV), or organic light emitting diode (OLED). As illustrated in FIG. 1, the film for improving the contrast has a micro-pattern, such as a stripe pattern, on bottom and top faces thereof. Here, when light is incident onto a display panel from the outside, and then is reflected to reach a field of vision of the observer together with light (image) emitted from the panel, the contrast is reduced. In other words, a transparent stripe pattern is formed on opposite faces of the film so as to prevent the light incident onto the panel at a preset angle (shading angle) or more from passing the film, thereby serving to reduce a rate of the light cast from and reflected to the outside among from the light emitted from the display panel. A contrast ratio under a daylight condition in which external light exists can be expressed by the following Equation 1. Thus, as the brightness of reflected light (the light cast from and reflected to the outside) is reduced, the contrast ratio is increased although the brightnesses of white light and black light are not changed, because the terms, denominator and numerator, of Equation 1 are simultaneously reduced.

[Equation 1]

$$contrast ratio ( Daylight condition ) = \frac{\begin{matrix}Brightness of W L + \\ Brightness of R L\end{matrix}}{\begin{matrix}Brightness of B L + \\ Brightness of R L\end{matrix}}$$

In Equation 1, WL is short for white light, RL for reflected light, and BL for black light.

Further, the film can be used as a security film functioning to interrupt the light when the image is observed at a position beyond a preset angle. In other words, the film of FIG. 1 is described from the viewpoint of the incident angle, but functions to interrupt the light, which is emitted from the display panel at an inclined angle beyond a preset angle.

Another example of the micro-patterned film includes a security film used for the touch pad of an apparatus such as an automated teller machine (ATM). In the case of the ATM, it is necessary to prevent an image containing an identification number or other important information from being displayed at another position beyond a field of vision of a user. In this case, it is preferable to ensure the security against all angles except the front of the touch pad. Thus touch pad is preferably designed so that a grid pattern as illustrated in FIG. 2, rather than the stripe pattern, is identically formed on top and bottom faces of the film.

Also, another example of the micro-patterned film includes a film for a navigation system used for a vehicle. This navigation system is also required to display an image only to a driver if possible. This is because, if the image is displayed in another inclined direction than a front direction, the image displayed on the navigation system may be made on a front, lateral or rear window of the vehicle, and thus serve as a factor of hindering the field of vision of the driver.

However, among the various optical films, all of the aforementioned optical films are required to have the parallel micro-patterns (i.e. the same top and bottom patterns overlapping completely when the films are viewed in front thereof) on the top and bottom faces thereof. Particularly, a pair of corresponding micro-patterns formed on the top and bottom faces of the film are preferably equal in width and position (excluding a position of a thickness direction) when viewed in a cross-section direction of the film.

When the patterns of the film have different widths and positions, there is a possibility of causing asymmetry with respect to a contrast improving effect, a security effect, etc. that can be obtained according to an angle at which the display device is viewed. For this reason, this ray serve as a factor of deteriorating a quality of image of the display device.

Nevertheless, the film having the foregoing micro-patterns has not yet been provided up to now. Furthermore, it is very difficult for the positions and widths to be equally maintained by, if any, the method of forming the micro-pattern on each face of the film, which has been known up to now, for instance, a printing method, a photo-lithography method, etc. for each face of the film. As such, the technology for forming the micro patterns on the film has not yet provided up to now.

### DISCLOSURE OF INVENTION

### Technical Problem

The present invention has been made to solve the foregoing problems with the prior art, and therefore an aspect of the present invention is to provide a method of manufacturing a film having micro-patterns, capable of controlling positions and widths of each pair of corresponding micro-patterns formed on front and rear faces of the film so as to be matched with each other, and a film manufactured using the same.

### Technical Solution

According to an aspect of the present invention, there is provided a method of manufacturing a film having micro patterns, which includes the steps of: forming a first micro-pattern on one face of the film; and forming a second micro-pattern, which has a geometry equal to that of the first micro-pattern, on the other face of the film by a photo-lithography method using the first micro-pattern formed on one face of the film as a photomask.

Here, the first micro-pattern may be formed by the photo-lithography method.

Further, the photo-lithography method may be performed by exposure, development, cleaning and drying after a photo-resist material is applied to the film.

Also, the photo-resist material, which is used when the second micro-pattern having the geometry equal to that of the first micro-pattern is formed, may be a positive photo-resist material.

Meanwhile, the photo-resist material may be applied on the film by one selected from the group consisting of direct gravure, reverse gravure, micro gravure, comma, slot die coating, slit coating, curtain coating, capillary coating, spray coating, dip coating, silk screen, and spin coating.

Further, the method may further include the step of pre-baking the applied photo-resist material before the exposure or post-baking the remaining micro-pattern after the development, cleaning and drying.

Here, the first micro-pattern may be formed by a printing method or an electroless plating method.

Further, the printed micro-pattern may be formed on the film by one selected from the group consisting of direct gravure, reverse gravure, micro gravure, off-set, reverse off-set, ink jet, and silk screen.

Also, the photo-lithography method may be performed by exposure, development, cleaning and drying after a photo-resist material is applied to the film.

Further, the method may further include the step of pre-baking the applied photo-resist material before the exposure or post-baking the remaining micro-pattern after the development, cleaning and drying.

Furthermore, the photo-resist material may be applied on the film by one selected from the group consisting of direct gravure, reverse gravure, micro gravure, comma, slot die coating, slit coating, curtain coating, capillary coating, spray coating, dip coating, silk screen, and spin coating.

According to another aspect of the present invention, there is provided a method of manufacturing a film having micro patterns, which includes the steps of: applying photo-resist materials to opposite faces of the film; and disposing a photomask above the film, performing exposure, development, cleaning, and drying on the opposite faces of the film, and obtaining the film having the micro-patterns on the opposite faces thereof.

Here, the photo-resist material may be applied on the film by one selected from the group consisting of direct gravure, reverse gravure, micro gravure, comma, slot die coating, slit coating, curtain coating, capillary coating, spray coating, dip coating, silk screen, and spin coating.

Meanwhile, the method may further include the step of pre-baking the applied photo-resist material before the exposure or post-baking the remaining micro-pattern after the development, cleaning and drying.

According to yet another aspect of the present invention, there is provided a film having micro-patterns manufactured using the method as described above, which includes multiple pairs of corresponding micro-patterns on front and rear faces of the film, and has a difference between widths of the corresponding micro-patterns within 20% of the width of the pattern formed on the front face of the film among each pair of patterns, and a distance difference between the central axes of each pair of corresponding patterns within 10% of the width of the pattern formed on the front face of the film among each pair of patterns.

Here, the film may be used as a film for improving a contrast, a film for security, and a film for a touch pad in a display device.

### Advantageous Effects

According to the present invention, the identical micro-patterns are formed on the opposite faces of the film, so that the film in which the patterns formed on the opposite faces thereof are controlled to have the same geometry can be obtained. The film can be used as various optical films having the micro-pattern on the faces thereof, such as a film for improving a contrast, a film for security, and a film for a touch pad.

Further, the method of manufacturing a micro-patterned film can provide a film, which is manufactured in a very simple manner and has a high precise micro-pattern compared to a known method.

### BRIEF DESCRIPTION OF THE DRAWINGS

The above objects, and other features and advantages of the present invention will become more apparent after a reading of the following detailed description when taken in conjunction with the drawings, in which:

FIG. 1 is a perspective view illustrating one example of a micro-patterned film;

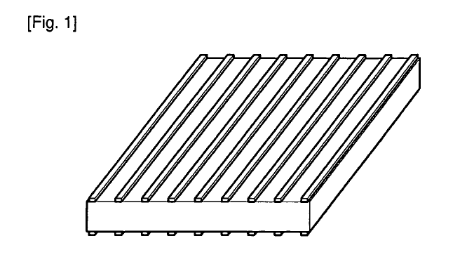

FIG. 2 is a schematic view illustrating one example of a film used to secure security in directions other than a front direction;

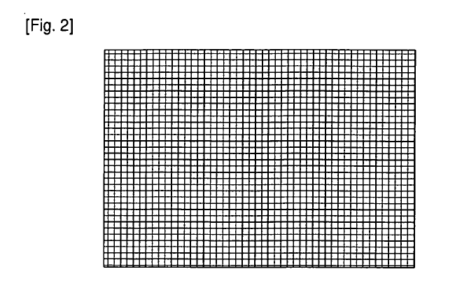

FIG. 3 is a process flow chart illustrating a first method of manufacturing a film having micro-patterns according to the present invention;

FIG. 4 is a process flow chart illustrating a second method of manufacturing a film having micro-patterns according to the present invention;

FIG. 5 is a process flow chart illustrating a third method of manufacturing a film having micro-patterns according to the present invention;

FIG. 6 is a schematic view for explaining a distance between central axes of corresponding patterns according to the present invention;

FIG. 7 is a process view illustrating a method of manufacturing a film having micro-patterns using a roll-to-roll process according to the present invention; and

FIG. 8 is a cross-sectional view illustrating one example of a film manufactured according to an embodiment of the present invention.

### BEST MODE FOR CARRYING OUT THE INVENTION

Hereinafter, exemplary embodiments of the invention will be described in detail with reference to the accompanying drawings.

The inventors of the present invention discovered that, when micro-patterns are independently formed on front and rear faces of a film as in the related art, it is difficult to eliminate a deviation in width and position even if a precise printing technique or an identical photo-resist mask is used. Thus, the inventors went deep into the study in order to overcome this problem, and reached the present invention in the long run.

In brief, the present invention is mainly characterized in that, when multiple pairs of micro-patterns are formed on front and rear faces of a film, each pair of corresponding front and rear micro-patterns make use of information on the same width and position, thereby having the same width and position.

There are various methods of enabling each pair of micro-patterns to use the same information on the width and position. Among them, a principal method will be described below as an example. First, a first micro-pattern is formed on one of the front and rear faces, and then the second micro-pattern is formed on the opposite face using the first micro-pattern as a photo-resist mask.

According to this method, since the first micro-pattern formed on one face is used as the mask for forming the second micro-pattern on the other face, the micro-patterns of the opposite faces can be exactly matched with each other in terms of the width and position.

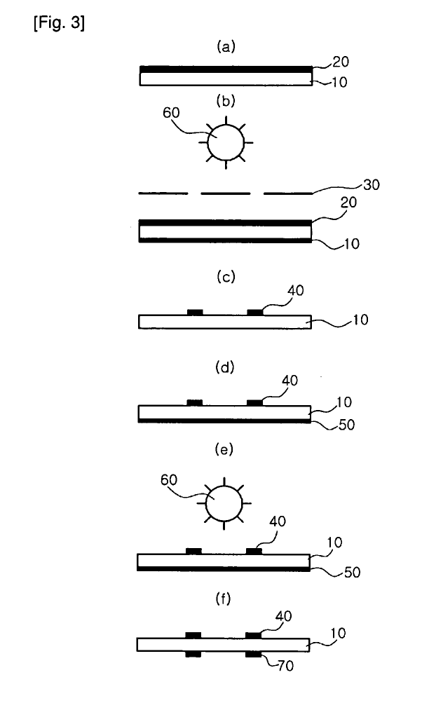

This method will be described below in greater detail with reference to FIG. 3. First, a first micro-pattern 40 is formed on one face of a film 10. In this step, either a photo-lithography method or a printing method can be used.

In order to form the micro-pattern on the film 10 using the photo-lithography method, it is necessary to apply a photo-resist material 20 to the face of the film (see FIG. 3(a)). The photo-resist material can be applied by direct gravure, reverse gravure, micro gravure, comma, slot die coating, slit coating, curtain coating, capillary coating, spray coating, dip coating, silk screen, spin coating, or the like.

As illustrated in FIG. 3, the film 10, to which the photo-resist material 20 is applied, is subjected to exposure with a photomask 30 installed thereon (see FIG. 3(b)), and is then developed, cleaned, and dried to form a micro-pattern 40 thereon (see FIG. 3(c)). At this time, the applied photo-resist material is pre-baked before the exposure, so that a firm coating layer can be formed. Further, according to circumstances, the remaining micro-pattern is post-baked after the developing, cleaning and drying, so that it can secure its strength.

Here, the micro-pattern 40 applied to one face of the film functions to interrupt light, and also serves as a photomask for forming another micro-pattern on the other face of the film later. Thus, the micro-pattern requires its optical density (OD) expressed by the following equation 2 to be limited to 0.5 or more. The OD of the pattern can be dependent on thickness and type of the applied material, but it can be easily obtained by a person skilled in the art through a change in detailed conditions.

OD=−log₁₀(I/I₀) [equation 2]

Further, as in the typical photo-lithography process, a light source 60 used for the exposure can use a high, medium or low pressure mercury lamp, a metal halide lamp, or the like. Further, a developing solution can be properly selected according to the type of the photo-resist material. Examples of the developing solution can include an alkaline aqueous solution such as tetramethyl ammonium hydroxide (TMAH) or KOH.

Meanwhile, in FIG. 3, the light reaches to the pattern 40 intended to be left behind by the photomask. In this case, the photo-resist material 20 preferably is a negative type. In contrast, in the case in which the light reaches to the pattern intended to be removed by the photomask, the photo-resist material preferably is a positive type. Thus, as long as the photomask 30 is properly selected from a photomask for the negative photo-resist and a photomask for the positive photo-resist, the photo-resist material is not particularly limited whether it is the negative type or the positive type.

Since a detailed method of forming the micro-pattern using the following photo-lithography process can be easily conducted by any person having ordinary skill in the art using a photo-lithography process that has already been well-known prior to the application of the present invention, a detailed description thereof will be made.

The film having the fine micro-pattern formed on one face thereof by the foregoing process can be obtained.

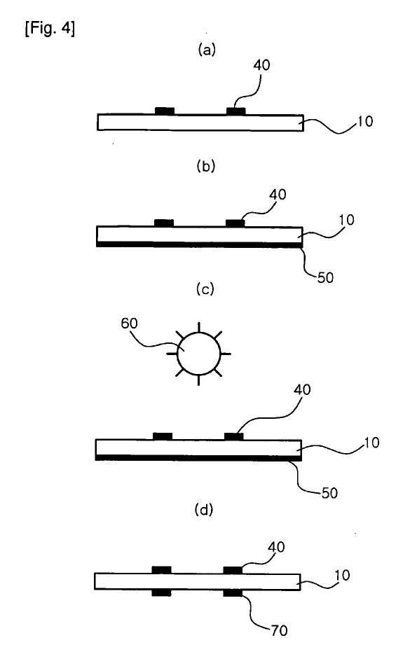

In order to obtain the film having the fine micro-pattern formed on one face thereof, a method of directly printing or coating the film so as to have the micro-pattern can be used as illustrated in FIG. 4 (see FIG. 4(a)), except the foregoing photo-lithography method.

The printing method may use any known method of forming a pattern on a film. For the printing, any method capable of forming the pattern, such as direct gravure, reverse gravure, micro gravure, off-set, reverse off-set, ink jet, silk screen or the like, can be used. Afterwards, the film on which the pattern is printed is dried. Thereby, the process of forming the pattern on one face of the film is completed.

Meanwhile, instead of the printing, an electroless plating method of a metallic pattern material can be considered. Here, the electroless plating refers to a process which electroplates metal without electrolysis. More specifically, when a part to which a catalyst is applied is immersed into a plating solution in which ions of metal to be plated are resolved, the catalyst reduces activation energy required for reduction of the metal ions, and thereby the metal ions are deposited on the part coated with the catalyst. In the present invention, in order to form the pattern on one face of the film using the electroless plating method, a catalyst material is coated on one face of a film so as to be same as a pattern to be formed, and then the film coated with the catalyst material is immersed into a plating solution. Thereby, the film, on which a metallic material is coated in a desired pattern, can be obtained. The catalyst material and the plating solution, both of which are required for the electroless plating, are not particularly restricted as long as they can be used for a typical electroless plating method. Thus, although a detailed procedure of the pattern formation is not described, it will be apparent to a person having ordinary skill in the art that the present invention can be repeatedly implemented without particular difficulty.

At this time, the pattern applied to one face of the film functions to interrupt the light, and also serves as the photomask for forming the pattern on the other face of the film in future. Thus, the pattern requires its OD to be limited to 0.5 or more. The OD of the pattern can be dependent on thickness and type of the applied material, but it can be easily obtained by a person skilled in the art through a change in detailed conditions.

The film having the first micro-pattern formed on one face thereof by the foregoing process can be obtained. Afterwards, it is necessary to perform a process of forming the second micro-pattern having the same geometry (shape and position) on the opposite face to the face having the first micro-pattern.

As illustrated in FIG. 3(d) through 3(f) and FIG. 4(b) through 4(d), the method of forming the second micro-pattern on the opposite face of the film is similar to that of forming the first micro-pattern on one face of the film using the photo-lithography method. In detail, a photo-resist material 50 is applied to the opposite face of the film (see FIGS. 3(d) and 4(b)), and is subjected to exposure (see FIGS. 3(e) and 4(c)), development, cleaning, and drying. Thereby, the micro-pattern is formed (see FIGS. 3(f) and 4(d)). Here, the pre-baking or the post-baking nay be selectively performed.

However, when the photo-resist material 50, which is applied to the opposite face of the film (the face on which the second pattern is formed), exposed to the light in order to obtain a desired pattern, a separate photomask is not used. This process is different from the process of forming the first pattern or the typical photo-lithography process. This is because the present invention is characterized in that the geometry of the first pattern is completely matched with that of the second pattern using the first pattern as the photomask for the second pattern. More specifically, when the photo-resist material for the second pattern 70 is coated and exposed, the face of the film which has the first pattern 40 is oriented toward a light source, and then the exposure is performed. In this case, the first pattern 40 serves as a good photomask due to high OD of the first pattern 40. Further, as the first pattern is projected onto the photo-resist material 50 for the second pattern, the remaining region other than the region having the same geometry as the first pattern 40 is exposed to the light.

At this time, the photo-resist material 50 applied to the opposite face of the film preferably is a positive type. Unlike the first pattern 40 in which the photomask is used for one selected from the negative photo-resist material and the positive photo-resist material, since the second pattern uses the first pattern 40 as only the positive photomask, the photo-resist material 50 for the second pattern preferably is the positive type.

The film, in which the geometries of the front and rear micro-patterns are highly matched with each other, can be obtained by the foregoing process. To sum up the method of manufacturing a micro-patterned film according to a first aspect of the present invention, the method includes the step of forming the first micro-pattern on one face of the film, and the step of forming the second micro-pattern, which has the same geometry as the first micro-pattern formed previously, on the other face of the film by the photo-lithography method using the first micro-pattern formed on one face of the film as the photomask. At this time, the first micro-pattern formed previously can be formed by the photo-lithography method printing method or the electroless plating method.

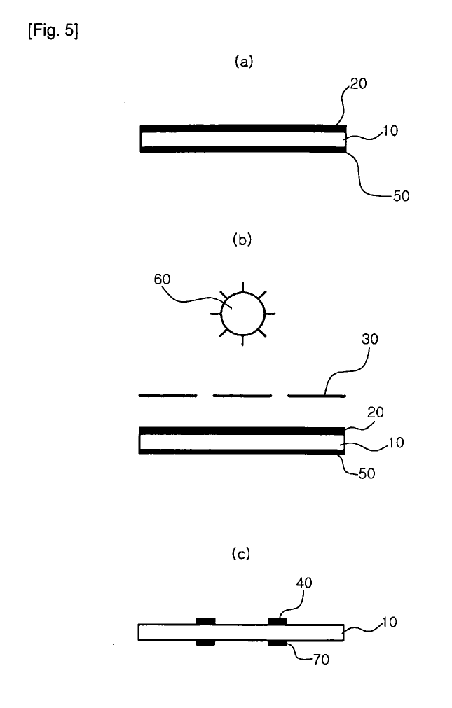

FIG. 5 illustrates a method of manufacturing a micro-patterned film according to a second aspect of the present invention. The method will be described below in detail. Unlike the first second aspect of the present invention, according to the second aspect of the present invention, photo-resist materials 20 and 50 are simultaneously applied to opposite faces of a film 10 (see FIG. 5(a)). These photo-resist materials 20 and 50 are applied as described above.

Thereafter, the film 10, on the opposite faces of which the photo-resist materials are coated, is subjected to exposure with a photomask 30 placed thereabove (see FIG. 5(b)). Because the photo-resist materials 20 and 50 are coated on the opposite faces of a film 10, the photo-resist materials 20 and 50 are photosensitized in the same geometry. Since the photomask can be selected from a photomask for the negative photo-resist material and a photomask for the positive photo-resist material for the exposure, the photo-resist material is not particularly limited to its type. However, since the patterns formed on the film are for interrupting the light, it is necessary to limit the photo-resist material such that the OD of the remaining pattern is 0.5 or more. Further, as in the second aspect of the present invention, in the case in which the photo-resist materials are applied to the opposite faces of the film, and are exposed at the same time, the light for exposure must transmit the photo-resist material of the front face of the film to photosensitive the photo-resist material of the rear face of the film. For this reason, too high OD of the pattern formed on the front face of the film is not preferable. Thus, an upper limit of the OD of the pattern formed on the front face of the film is preferably set to 5. The OD of the pattern can be dependent on thickness and type of the applied material, but it can-be easily obtained by a person skilled in the art through a change in detailed conditions.

Afterwards, the exposed photo-resist material is developed, cleaned, and dried, so that the film, on the opposite faces of which the micro-patterns 40 and 70 are formed at the same time, can be obtained (FIG. 5(c)). At this time, the applied photo-resist material is pre-baked before the exposure, so that a firm coating layer can be formed. Further, according to circumstances, the remaining micro-pattern is post-baked after the developing, cleaning and drying, so that it can secure its strength.

In brief, the method of manufacturing a micro-patterned film according to a second aspect of the present invention includes: the step of applying photo-resist materials to the opposite faces of the film; and disposing the photomask above the film, performing the photo-lithography processes (exposure, development, cleaning, and drying) on the opposite faces of the film, and obtaining the film having the micro-patterns on the opposite faces thereof.

The other photo-lithography processes, which are not yet described, are the same as in the foregoing description.

The micro-patterned film of the present invention, which is formed by the foregoing processes, can be used as a film for improving a contrast, a film for security, and a film for a touch pad.

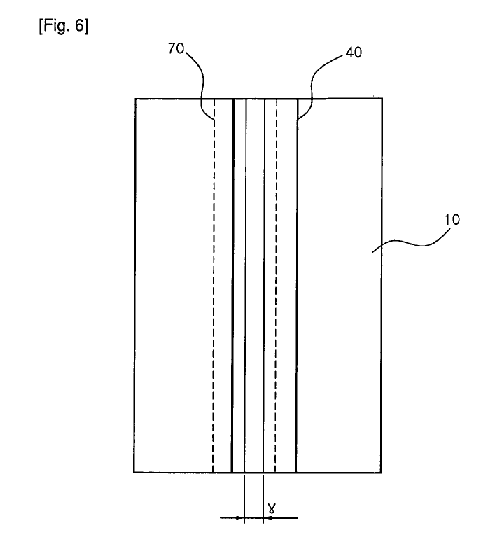

In the present invention, the film manufactured by the foregoing method is very excellent in precision of the width and position of the pattern compared to that manufactured by a known method of independently forming patterns on front and rear faces of a film, and has a difference between the widths of the corresponding micro-patterns within 20% of the width of the pattern formed on the front face of the film among each pair of patterns, and a horizontal distance g between the central axes of the pair of corresponding patterns as illustrated in FIG. 6 within 10% of the width of the pattern formed on the front face of the film among each pair of patterns.

Further, the film of the present invention can have various patterns. For example, in the case in which the film is used as a film for improving a contrast, a film for security, and a film for a touch pad in a display device such as plasma display panel (PDP), liquid crystal display (LCD), rear projection television (RPTV), or organic light emitting diode (OLED), the pattern preferably includes a stripe pattern or a grid pattern. In addition, even in the case in which the top and bottom patterns are identical to each other, the pattern includes a honeycomb pattern, a specific character pattern, or the like, including the patterns. All these patterns can be realized by the present invention. Thus, it should be noted that the present invention is not limited to such a pattern.

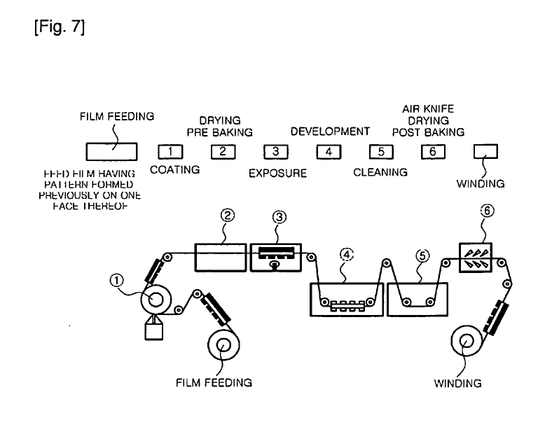

The film manufactured by the method of the present invention has another advantage in that the micro-patterned film can be manufactured by a roll-to-roll process as illustrated in FIG. 7. Here, the roll-to-roll process can form a desired pattern until the film wound around a roll is unwound, and then is wound around the next roll again. According to the present invention, the roll-to-roll process can be implemented by the method as illustrated in FIG. 7 as one example, or its similar method. Of course, the roll-to-roll process can be continuously performed until the roll is unwound and wounded as illustrated in FIG. 7, but it can be discontinuously performed in a manner such that the process is stopped in a proper step, and then proceeds to the next step.

In the case in which the photo-resist material is coated on the film using the roll-to-roll process, any one of the foregoing coating methods such as direct gravure, reverse gravure, micro gravure, comma, slot die coating, slit coating, curtain coating, capillary coating, spray coating, dip coating, and so on is preferably used. In the case in which the pattern is directly printed on the film, any one of the foregoing printing methods such as direct gravure, reverse gravure, micro gravure, off-set, reverse off-set, ink jet and so on is preferably used.

Further, the coating of the photo-resist material or the printing of the pattern can be surely performed by a batch process of independently forming the pattern on discontinuous films having a sheet or plate shape, in addition to the roll-to-roll process illustrated in FIG. 7. At this time, in the case in which the photo-resist material is coated by the batch process, any one of the foregoing coating methods such as silk screen, spin coating, dip coating and so on is preferably used. In the case in which the pattern is directly printed on the film, any one of the foregoing printing methods such as silk screen, off-set, reverse off-set, ink jet and so on is preferably used.

Further, a material for the micro-patterned film of the present invention, that is, a part on which the pattern is formed, is not particularly limited as long as it is a transparent thin film structure. Examples of the material may include materials having the shape of a roll, sheet or plate, such as a polyethylene terephthalate (PET) film, atriacelyl cellulose (TAC) film, apolyethylene naphthalate (PEN) film, a glass or acryl based film, a polyolefin based film, a polymethylmethacrylate (PMMA) film, and a polycarbonate (PC) film.

### Mode for the Invention

Hereinafter, exemplary embodiments of the present invention will be described below in greater detail. However, it should be noted that these exemplary embodiments of the present invention are merely described for illustrative purposes, and are not meant to limit the invention. Thus, the scope of the present invention is defined by the appended claims and equivalents thereof.

### EXAMPLES

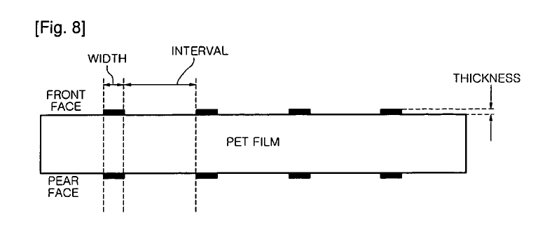

A micro-patterned film as illustrated in FIG. 8 was manufactured as in the following Examples. As illustrated in FIG. 8, the film intended to be manufactured in each Example are to form a plurality of patterns having a width of 32 μm(micrometer) and an interval of 69 μm(micrometer) on a PET film having a thickness of 100 μm(micrometer), in which the patterns are formed in pairs on front and rear faces of the PET film.

### Example 1

A negative photo-resist material (CK series material of Tokyo Ohaka Kogyo Co.) was uniformly applied on a film at a thickness of about 10 μm(micrometer) using a spin coater. The applied photo-resist material was pre-baked at 90° C.(Celsius) for 1 minute. At this time, the OD of a visible light range was about 3.5 Afterwards, the photo-resist material was exposed using a photomask having a desired shape. A light source for the exposure used a high-pressure mercury lamp. After the exposure, the film was immersed into an aqueous solution of 0.04 wt % KOH, and then was cleaned and dried. Thereby, the PET film having a micro-pattern on one face thereof was obtained. A positive photo-resist material (in which a carbon black material was mixed with a JC-800 material available from DONGJIN SEMICHEM in order to adjust transmissibility) was coated on the PET film at a thickness of about 10 μm(micrometer) using a spin coater, and then was pre-backed at 90° C.(Celsius) for 1 minute. After the previously formed pattern was oriented toward the light source, the exposure, development, cleaning and drying were performed as in the method described above. However, a development solution used an aqueous solution of 2.38 wt % TMAH.

### Example 2

Stripe patterns having a width of 33 μm(micrometer) were formed on a film at an interval of 69 μm(micrometer) by a gravure printing method using printing ink (8511 material of Encres Dubuit (France)). A positive photo-resist material was coated on the opposite face of the film at a thickness of about 10 μm(micrometer) using a spin coater, and then was pre-backed at 90° C.(Celsius) for 1 minute. After the previously formed pattern was oriented toward a light source, the exposure, development, cleaning and drying were performed as in the method described above.

### Example 3

The negative photo-resist material of Example 1 was coated on opposite faces of a PET film as in Example 1. The photo-resist materials coated on the opposite faces of the PET film were exposed at the same time using a photomask. To easily expose the films on opposite sides simultaneously, a high-pressure mercury lamp was used as a light source. After the exposure, the development, cleaning and drying were performed as in the method described above.

In the films having the micro-pattern formed as in Examples 1, 2 and 3, a difference between widths of corresponding patterns was maximum 1 μm(micrometer), and a distance between central axes was maximum 0.5 μm(micrometer).

1. A method of manufacturing a film having micro patterns, comprising:
forming a first micro-pattern on one face of the film; and
forming a second micro-pattern, which has a geometry equal to that of the first micro-pattern, on the other face of the film by a photo-lithography method using the first micro-pattern formed on one face of the film as a photomask.

2. A method of claim 1, wherein the first micro-pattern is formed by the photo-lithography method.

3. A method of claim 1, wherein the photolithography method is performed by exposure, development, cleaning and drying after a photo-resist material is applied to the film.

4. A method of claim 3, wherein the photo-resist material, which is used when the second micro-pattern having the geometry equal to that of the first micro-pattern is formed, comprises a positive photo-resist material.

5. A method of claim 3, wherein the photo-resist material is applied on the film by one selected from the group consisting of direct gravure, reverse gravure, micro gravure, comma, slot die coating, slit coating, curtain coating, capillary coating, spray coating, dip coating, silk screen, and spin coating.

6. A method of claim 3, further comprising the step of pre-baking the applied photo-resist material before the exposure of post-baking the remaining micro-pattern after the development, cleaning and drying.

7. The method of claim 1, wherein the first micro-pattern is formed by a printing method or a electroless plating method.

8. The method of claim 7, wherein the printed micro-pattern is formed on the film by one selected from the group consisting of direct gravure, reverse gravure, micro gravure, set-off, reverse of-set, ink jet, and silk screen.

9. The method of claim 7, wherein the photo-lithography method is performed by exposure, development, cleaning and drying after a photo-resist material is applied to the film.

10. The method of claim 9, further comprising the step of pre-baking the applied photo-resist material before the exposure or post-baking the remaining micro-pattern after the development, cleaning and drying.

11. The method of claim 9, wherein the photo-resist material is applied on the film by one selected from the group consisting of direct gravure, reverse gravure, micro gravure, comma, slot die coating, slit coating, curtain coating, capillary coating, spray coating, dip coating, silk screen, and spin coating.

12. The method of manufacturing a film having micro patterns, comprising:
applying photo-resist materials to opposite faces of the film; and
disposing of photomask above the film, performing exposure, development, cleaning, and drying on the opposite faces of the film, and obtaining the film having the micro-patterns on the opposite faces thereof.

13. The method of claim 12, wherein the photo-resist material is applied on the film by one selected from the group consisting of direct gravure, reverse gravure, micro gravure, comma, slot die coating, slit coating, curtain coating, capillary coating, spray coating, dip coating, silk screen, and spin coating.

14. The method of claim 12, further comprising the step of pre-baking the applied photo-resist material before the exposure or post-baking the remaining micro-pattern after the development, cleaning and drying.

15. A film having micro-patterns manufactured using the method defined in claim 1, comprising multiple pairs of corresponding micro-patterns on front and rear faces of the film, and having a difference between widths of the corresponding micro-patterns within 20% of the width of the pattern formed on the front face of the film among each pair of patterns, and a distance difference between the central axes of each pair of corresponding patterns within 10% of the width of the pattern formed on the front face of the film among each pair of patterns.

16. The film of claim 15, wherein the film is used as a film for improving a contrast, a film for security, and a film for a touch pad in a display device.

17. A film having micro-patterns manufactured using the method defined in claim 12, comprising multiple pairs of corresponding micro-patterns on front and rear faces of the film, and having a difference between widths of the corresponding micro-patterns within 20% of the width of the pattern formed on the front face of the film among each pair of patterns, and a distance difference between the central axes of each pair of corresponding patterns within 10% of the width of the pattern formed on the front face of the film among each pair of patterns.

18. The film of claim 17, wherein the film is used as a film for improving a contrast, a firm for security, and a film for a touch pad in a display device.

19. A method of claim 2, wherein the photo-lithography method is performed by exposure, development, cleaning and drying after a photo-resist material is applied to the film.

20. A film having micro-patterns manufactured using the method defined in claim 12, comprising multiple pairs of corresponding micro-patterns on front and rear faces of the film, and having a difference between widths of the corresponding micro-patterns within 20% of the width of the pattern formed on the front face of the film among each pair of patterns, and a distance difference between the central axes of each pair of corresponding patterns within 10% of the width of the pattern formed on the front face of the film among each pair of patterns.
